(19) United States
(12) Patent Application Publication
(10) Pub. No.: US 2017/0150624 A1
(43) Pub. Date: May 25, 2017

(54) BACK PLATE WITH A TUNABLE CURVATURE, BACKLIGHT MODULE AND CURVED DISPLAY DEVICE HAVING THE SAME

(71) Applicant: BOE TECHNOLOGY GROUP CO., LTD., Beijing (CN)

(72) Inventors: Yuxin Bi, Beijing (CN); Jiyang Shao, Beijing (CN)

(73) Assignee: BOE TECHNOLOGY GROUP CO., LTD., Beijing (CN)

(21) Appl. No.: 15/030,587

(22) PCT Filed: Dec. 10, 2015
(86) PCT No.: PCT/CN2015/096899

§ 371 Date: Apr. 19, 2016

(30) Foreign Application Priority Data
May 27, 2015 (CN) 201510278079.9

(51) Int. Cl. H05K 5/02; H05K 5/00

(52) U.S. Cl. CPC H05K 5/0247; H05K 5/0017

(57) ABSTRACT

The present invention discloses a back plate having a curvature of the back plate is tunable in response to a curvature control signal. The back plate comprises a back plate main body and a dielectric elastomer layer secured to the back plate main body. The dielectric elastomer layer undergoes elastic deformation in response to a curvature control signal.

### CROSS-REFERENCE TO RELATED APPLICATION

This application claims priority to Chinese Patent Application No. 201510278079.9, filed May 27, 2015, the contents of which are incorporated by reference in the entirety.

### FIELD OF THE INVENTION

The present invention relates to display technology, and more particularly, to a back plate with a tunable curvature, a backlight module and a curved display device having the same.

### BACKGROUND OF THE INVENTION

Convention display devices are usually flat. In recent years, display devices having a curved display surface have been proposed for design or other reasons. In these proposals, typically a display panel is first bent by force to achieve a predetermined, fixed curvature. The bent display panel is then secured to a mold frame for use in a backlight module. However, such display devices have problems such as displacement of display panel and uneven display in the liquid crystal display caused by the stress resulting from the display panel being bent. In addition, the curvature in such display devices is not tunable.

### SUMMARY OF THE CLAIMED INVENTION

In one aspect, the present invention provides a back plate comprising a back plate main body and a dielectric elastomer layer secured to the back plate main body. The dielectric elastomer layer undergoes elastic deformation in response to a curvature control signal. The curvature of the back plate is tunable in response to a curvature control signal. Optionally, the back plate further comprises a flexible insulating layer between the back plate main body and the dielectric elastomer layer. Optionally, the dielectric elastomer layer is, directly or indirectly, coupled to a curvature control module capable of generating the curvature control signal. Optionally, the curvature control module comprises a curvature control unit coupled to a curvature control signal generating unit; the curvature control unit generates a driver control signal in response to user input, and the curvature control signal generating unit generates the curvature control signal in response to the driver control signal. Optionally, the curvature control module is, directly or indirectly, coupled to the dielectric elastomer layer at a plurality of locations on the dielectric elastomer layer, each of which is capable of independently undergoing elastic deformation in response to the curvature control signal from the curvature control module; and the sum of the elastic deformation results in the tunable curvature in the back plate. Optionally, the elastic deformation is generated in response to a plurality of curvature control signals generated by the curvature control signal generating unit, each curvature control signal causes distinct deformation in each of the plurality of locations. Optionally, the plurality of curvature control signals are independently generated by the curvature control signal generating unit. Optionally, the plurality of locations are evenly distributed on the dielectric elastomer layer. Optionally, the dielectric elastomer layer is coupled to the curvature control module at a plurality of locations through a plurality of conductor wires. Optionally, the plurality of locations correspond to a plurality of independent segments in the dielectric elastomer layer. Optionally, the dielectric elastomer layer is secured to the back plate main body by a glue or a screw. Optionally, the dielectric elastomer layer is secured to the back plate main body by a plurality of screws, the plurality of screws are evenly distributed throughout the dielectric elastomer layer when secured to the back plate main body. Optionally, the dielectric elastomer layer has a unibody structure. Optionally, the curvature control signal is a voltage signal.

In another aspect, the present invention provides a backlight module comprising the back plate of the present invention.

In another aspect, the present invention provides a curved display device comprising a display panel and the backlight module of the present invention. Optionally, the curved display device further comprises a curvature control unit and a curvature control signal generating unit; wherein the curvature control unit generates a driver control signal in response to user input, and the curvature control signal generating unit generates the curvature control signal in response to the driver control signal. Optionally, the curvature control unit is disposed within a field programmable gate array (FPGA) in the curved display device.

In another aspect, the present invention provides a method of manufacturing a back plate. The method comprises providing a back plate main body; providing a dielectric elastomer layer; and securing the dielectric elastomer layer to the back plate main body.

In another aspect, the present invention provides a method of manufacturing a display device. The method comprises providing a back plate of the present invention; disposing the back plate in a mold frame; disposing a light guide plate in the mold frame; and disposing a display panel including a display area in the mold frame.

### BRIEF DESCRIPTION OF THE FIGURES

FIG. 1 shows a cross-sectional view of a back plate according to an embodiment of the present invention.

FIG. 2 is a diagram illustrating the structure of a dielectric elastomer layer according to an embodiment of the present invention.

FIG. 3 is a diagram illustrating the structure a dielectric elastomer layer according to another embodiment of the present invention.

FIG. 4 shows a cross-sectional view of a curved display device according to an embodiment of the present invention.

### DETAILED DESCRIPTION OF THE INVENTION

The disclosure will now described more specifically with reference to the following embodiments. It is to be noted that the following descriptions of preferred embodiments are presented herein for purpose of illustration and description only. It is not intended to be exhaustive or to be limited to the precise form disclosed.

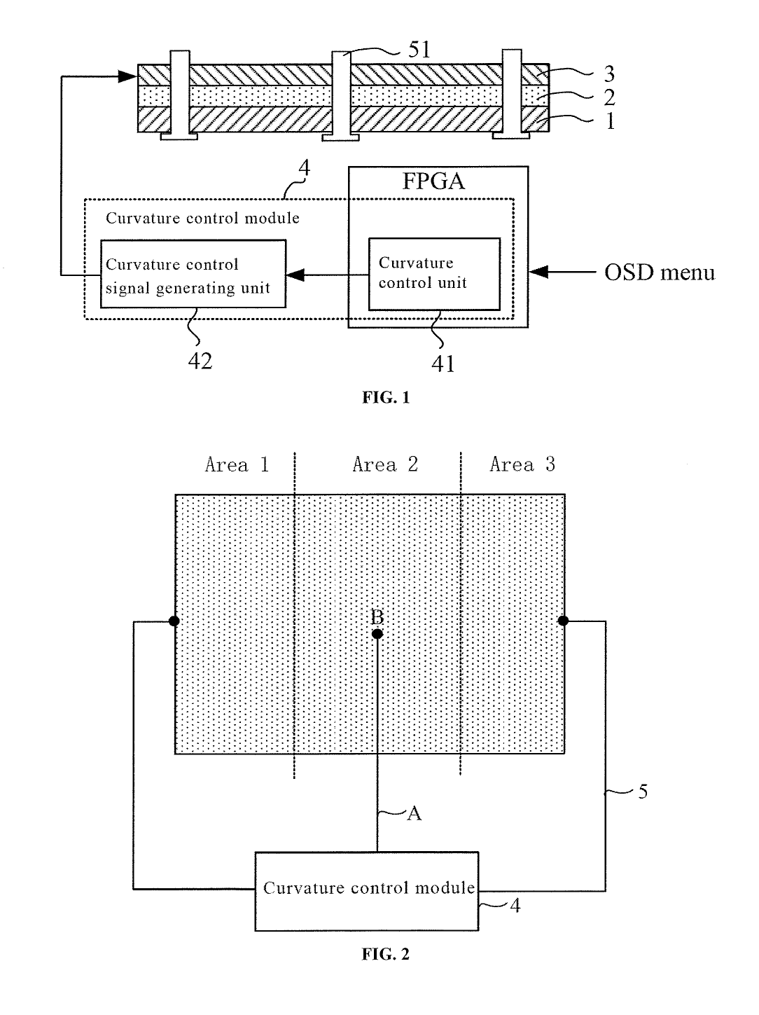

FIG. 1 is a cross-sectional schematic view of a back plate according to an embodiment of the invention. Referring to FIG. 1, a back plate in the embodiment includes a back plate main body 1 and a dielectric elastomer layer 3. The dielectric elastomer layer 3 is secured to the back plate main body 1, for example, using a screw 51.

The curvature of the back plate is tunable in response to a curvature control signal. Referring to FIG. 1, the back plate in the embodiments is coupled to a curvature control module 4, which is capable of generating a curvature control signal thereby tuning the curvature of the back plate. Typically, the dielectric elastomer layer 3 is coupled to the curvature control module 4, and undergoes elastic deformation in response to the curvature control signal from the curvature control module 4. The curvature control module 4 can be disposed internally or externally (e.g., remote control) to the back plate. The curvature control module 4 generates curvature control signal in response to user input.

Referring to FIG. 1, the curvature control module 4 in the embodiment includes a curvature control unit 41 and a curvature control signal generating unit 42. The curvature control unit 41 and the curvature control signal generating unit 42 can be integrated or disposed separately as shown in FIG. 1. The curvature control unit 41 is coupled to the curvature control signal generating unit 42, which in turn is coupled to the dielectric elastomer layer 3. In response to user input, the curvature control unit 41 is capable of generating a driver control signal. In response to the driver control signal, the curvature control signal generating unit 42 generates the curvature control signal thereby tuning the curvature of the dielectric elastomer layer 3 and the back plate. Optionally, the curvature control unit 41 and the curvature control signal generating unit 42 can be integrated as one single unit, e.g., a curvature control unit 41, which generates both a driver control signal and a curvature control signal, or directly generates the curvature control signal in response to user input.

As discussed above, the curvature control module 4 can be disposed internally or externally to the back plate, or can be disposed partially internally and partially externally to the back plate. For example, the curvature control signal generating unit 42 can be disposed internally to the back plate whereas the curvature control unit 41 is disposed externally to the back plate. The curvature control signal and/or the driver control signal can be any suitable form of signal, for example, current signal, voltage signal, charge signal, data signal.

The dielectric elastomer layer 3 is made of dielectric elastomer material capable of being subject to deformation in response to the curvature control signal, e.g., a voltage signal. A dielectric elastomer material refers to a polymer material having an electric field-induced electrostrictive strain. The dielectric elastomer material is not particularly limited, and includes all polymer material having an electrical insulating property and structurally an elastic restoring force. Examples of dielectric elastomer material include natural rubber, silicone rubber, acrylic rubber, copolymer, polyvinylidene fluoride-based polymers, acrylic-based polymers, urethane-based polymers, silicone-based polymers, thermoplastic elastomers, polybutadiene, isoprene rubber, nitrile rubber (NBR), ethylene propylene rubber (EPDM), styrene-butadiene rubber (SBR), chloroprene rubber (CR), hydrogenated nitrile rubber, or the like. The dielectric elastomer layer 3 can be constructed of a single unibody structure or of multiple segments.

The back plate main body can be made of any suitable material, for example, an electrical conductive material or an insulating material. When the back plate main body is made of an electrical conductive material, e.g., a metal material, the curvature control signal intended for deforming one local area of the back plate can be transmitted to the entire dielectric elastomer layer 3 via the back plate main body 1, i.e., the curvature control signal is not limited to the local area. Consequently, the entire dielectric elastomer layer is deformed by the curvature control signal intended for deforming one local area. Optionally, the dielectric elastomer layer 3 and the back plate main body 1 are insulated with each other.

Referring to FIG. 1, the back plate in the embodiment can further include a flexible insulating layer 2 disposed between the back plate main body 1 and the dielectric elastomer layer 3. The flexible insulating layer 2 insulates the main body 1 from the elastomer layer 3. Due to this insulation, the curvature control signal intended for deforming one local area will not be transmitted to the entire dielectric elastomer layer 3 through the back plate main body 1. Without the interference of an electrical conductive main body 1, independent control of deformation in each local area becomes possible. When a flexible insulating layer 2 is used, the dielectric elastomer layer 3, the flexible insulating layer 2, and the back plate main body can be secured together, for example, using a glue (e.g., a super glue) or a screw 51. When the back plate main body is made of an insulating material, the use of a flexible insulating layer 2 is optional. In some embodiments, a flexible insulating layer 2 is not used. The dielectric elastomer layer 3 can be secured directly to the back plate main body 1, for example, using a glue (e.g., a super glue) or a screw 51. When a plurality of screws 51 is used, they can be evenly distributed throughout the dielectric elastomer layer 3.

Referring to FIG. 1, the dielectric deformation layer 3 is secured to the back plate main body 1. The back plate main body 1 is assembled into the backlight module through a mold frame, and the display panel is secured to the backlight module. The dielectric deformation layer 3 undergoes elastic deformation and generates curvature in response to a control signal from the curvature control module 4. All secured together to the dielectric deformation layer 3, the back plate main body 1, the backlight module and the display panel undergo deformation together with the dielectric deformation layer 3, resulting in a tunable curvature in the display panel. The deformation occurring in any local area of the dielectric elastomer layer 3 induces deformation in corresponding areas in the back plate main body 1, the backlight module and the display panel.

FIG. 2 is a diagram illustrating the structure of a dielectric elastomer layer according to an embodiment of the present invention. Referring to FIG. 2, the dielectric elastomer layer in the embodiment has a unibody structure. The dielectric elastomer layer can be coupled to the curvature control unit at a plurality of locations, for example, through a plurality of conductor wires 5. Each conductor wire independently transmits a curvature control signal generated by the curvature control module 4 (e.g., the deformation control signal generating unit 42) to each location within the dielectric elastomer layer 3. In response, each location independently undergoes a distinct elastic deformation, thereby achieving independent control of deformation in each location. Accumulating all deformation in all locations together, the sum of the elastic deformation results in the tunable curvature in the back plate. In some embodiments, the plurality of locations are evenly distributed on the dielectric elastomer layer 3.

Referring to FIG. 2, a conductor wire 5 in the embodiment transmits the curvature control signal to the dielectric elastomer layer 3 at contact point B. The intensity of the curvature control signal on the layer 3 gradually decreases as the inverse of the distance from the contact point B. Thus, the deformation on the layer 3 also gradually decreases as the inverse of the distance from the contact point B. A curvature control signal transmitted to the layer 3 via contact point B can only effectively deform a limited area surrounding B, e.g., Area 2 in FIG. 2. FIG. 2 illustrates an exemplary way of dividing the elastomer layer 3 into multiple local areas (e.g., Areas 1-3). The range of the local area can be experimentally determined, and can be defined in any suitable manner (e.g., as a circle, square, eclipse, etc.). In some embodiments, the range of the local areas can partially overlap. By dividing the elastomer layer 3 into multiple local areas, the intensity and direction of elastic deformation in each area can be effectively controlled, resulting in a more accurate tuning of curvature in the dielectric elastomer layer 3. In some embodiments, the plurality of contact points are evenly distributed throughout the dielectric elastomer layer 3.

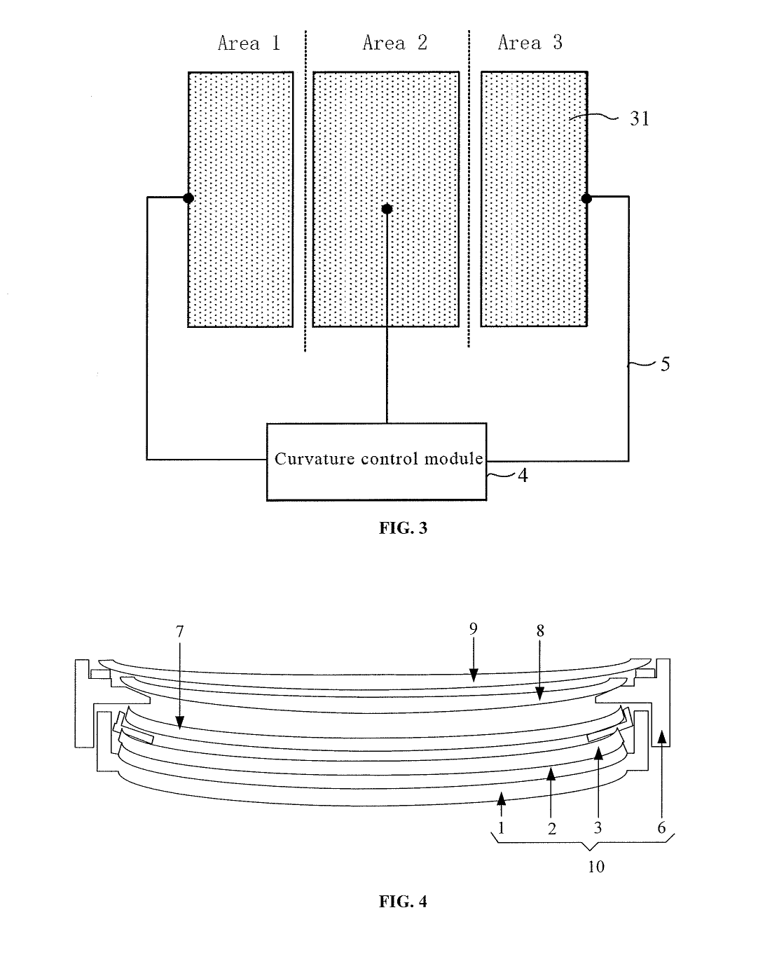

FIG. 3 is a diagram illustrating the structure a dielectric elastomer layer according to another embodiment of the present invention. Referring to FIG. 3, the dielectric elastomer layer 3 in the embodiment includes a plurality of independent segments 31. The curvature control module 4 can be coupled to the dielectric elastomer layer at a plurality of locations, for example, through a plurality of conductor wires 5. Each conductor wire independently transmits a curvature control signal generated by the curvature control module 4 (e.g., the deformation control signal generating unit 42) to each segment 31 within the dielectric elastomer layer 3. In response, each segment independently undergoes a distinct elastic deformation. Independent, zoned control of deformation in each segment can be achieved. Accumulating all deformation in all segments together, the sum of the elastic deformation results in the tunable curvature in the back plate. In some embodiments, the plurality of segments are evenly distributed on the dielectric elastomer layer 3.

Referring to FIG. 3, a conductor wire 5 in the embodiment transmits the curvature control signal to the dielectric elastomer layer 3 at a contact point. The intensity of the curvature control signal on the layer 3 gradually decreases as the inverse of the distance from the contact point. Thus, the deformation on the layer 3 also gradually decreases as the inverse of the distance from the contact point. A curvature control signal transmitted to the layer 3 via contact point can only effectively deform a limited area surrounding the contact point, e.g., the segment assigned as Area 2 in FIG. 3. FIG. 3 illustrates an exemplary embodiment having multiple segments (e.g., the segments assigned as Areas 1-3). The segments can be defined in any suitable manner for making the dielectric elastomer layer 3. By having multiple segments in the elastomer layer 3, the intensity and direction of elastic deformation in each segment can be effectively controlled, resulting in a more accurate tuning of curvature in the dielectric elastomer layer 3. In some embodiments, the plurality of segments are evenly distributed on the dielectric elastomer layer 3.

Each segment can be coupled to the curvature control module 4 through one single conductor wire 5 or a plurality of conductor wires 5. When each segment is coupled to the curvature control module 4 through a plurality of conductor wires 5, each conductor wire within one segment can be connected to a distinct location in the segment thereby further dividing a segment into a plurality of sub-segments. Zoned deformation control of each individual segment can be achieved by transmitting curvature control signals to multiple sub-segments within one segment.

In another aspect, the present invention provides a backlight module having a mold frame and a matching back plate with a tunable curvature. FIG. 4 shows a cross-sectional view of a curved display device according to an embodiment of the present invention. Referring to FIG. 4, the curved display device includes a display panel 9, an optical film 8, a light guide plate 7, and a backlight module 10. The display panel 9 is secured to the mold frame 6 of a backlight module 10.

In another aspect, the present invention also provides a curved display device having a display panel and a backlight module. In some embodiments, the curved display device includes a curvature control unit 41 and curvature control signal generating unit 42 coupled to the curvature control unit 41. In response to user input, the curvature control unit 41 is capable of generating a driver control signal. In response to the driver control signal, the curvature control signal generating unit 42 generates the curvature control signal thereby tuning the curvature of the dielectric elastomer layer 3 and the back plate. Optionally, the curvature control unit 41 is placed within a field programmable gate array (FPGA) within the curved display device. A user can adjust the curvature of the back plate 1 and the display device using on-screen display (OSD) menu.

In another aspect, the present invention provides a method of manufacturing a back plate. The method comprises providing a back plate main body; providing a dielectric elastomer layer; and securing the dielectric elastomer layer to the back plate main body.

In another aspect, the present invention provides a method of manufacturing a display device. The method comprises providing a back plate with a tunable curvature; disposing the back plate in a mold frame; disposing a light guide plate in the mold frame; and disposing a display panel including a display area in the mold frame.

As used herein, the term “couple” or “coupled” is intended to mean either a direct or indirect electrical connection. Thus, if a first device is coupled to a second device, that connection may be through a direct electrical connection, or through an indirect electrical connection via other devices and connections. Exemplary electrical connections include, but are not limited to, a hard-wired electrical connection as well as electrical communication established remotely between the devices, such as by infrared signals, RF signals, or the like. As used herein, the term “tunable”or “tuning” means that characteristics, e.g., the curvature of a back plate or a display panel, can be selected to provide a desired operating result. The term “tunable curvature” is typically applied to a back plate or a display panel, wherein the curvature of the back plate or display panel can be varied in a controlled manner over some range.

The foregoing description of the preferred embodiments of the invention has been presented for purposes of illustration and description. It is not intended to be exhaustive or to limit the invention to the precise faun or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to particularly preferred exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

1. A back plate comprising:
a back plate main body; and
a dielectric elastomer layer secured to the back plate main body;
wherein the dielectric elastomer layer undergoes elastic deformation in response to a curvature control signal, and curvature of the back plate is tunable in response to the curvature control signal.

2. The back plate according to claim 1, further comprising a flexible insulating layer between the back plate main body and the dielectric elastomer layer.

3. The back plate according to claim 1, wherein the dielectric elastomer layer is coupled to a curvature control module capable of generating the curvature control signal.

4. The back plate according to claim 3, wherein the curvature control module is, directly or indirectly, coupled to the dielectric elastomer layer at a plurality of locations on the dielectric elastomer layer, each of which is capable of independently undergoing elastic deformation in response to the curvature control signal from the curvature control module; and the sum of the elastic deformation results in the tunable curvature in the back plate.

5. The back plate according to claim 5, wherein the elastic deformation is generated in response to a plurality of curvature control signals generated by the curvature control signal generating unit, each curvature control signal causes distinct deformation in each of the plurality of locations.

6. The back plate according to claim 6, wherein the plurality of curvature control signals are independently generated by the curvature control signal generating unit.

7. The back plate according to claim 5, wherein the plurality of locations are evenly distributed on the dielectric elastomer layer.

8. The back plate according to claim 5, wherein the dielectric elastomer layer is coupled to the curvature control module at a plurality of locations through a plurality of conductor wires.

9. The back plate according to claim 5, wherein the plurality of locations correspond to a plurality of independent segments in the dielectric elastomer layer.

10. The back plate according to claim 1, wherein the dielectric elastomer layer is secured to the back plate main body by a glue or a screw.

11. The back plate according to claim 11, wherein the dielectric elastomer layer is secured to the back plate main body by a plurality of screws, the plurality of screws are evenly distributed throughout the dielectric elastomer layer when secured to the back plate main body.

12. The back plate according to claim 1, wherein the dielectric elastomer layer has a unibody structure.

13. The back plate according to claim 1, wherein the curvature control signal is a voltage signal.

14. A backlight module comprising the back plate according to claim 1.

15. A curved display device comprising a display panel and a backlight module comprising the back plate according to claim 1.

16. The curved display device claim 16, further comprising a curvature control unit and a curvature control signal generating unit; wherein the curvature control unit generates a driver control signal in response to user input, and the curvature control signal generating unit generates the curvature control signal in response to the driver control signal.

17. The curved display device according to claim 15, wherein the curvature control unit is disposed within a field programmable gate array (FPGA) in the curved display device.

18. A method of manufacturing a back plate of claim 1, comprising:
providing a back plate main body;
providing a dielectric elastomer layer; and
securing the dielectric elastomer layer to the back plate main body.

19. A method of manufacturing a display device, comprising:
providing a back plate of claim 1;
disposing the back plate in a mold frame;
disposing a light guide plate in the mold frame; and
disposing a display panel including a display area in the mold frame.
